(19) United States
(12) Patent Application Publication
(10) Pub. No.: US 2018/0327907 A1
(43) Pub. Date: Nov. 15, 2018

(54) METHOD FOR PRODUCING ALUMINUIM OXIDE AND/OR NITRIDE

(71) Applicant: KOBUS SAS, MONTBONNOT-SAINT-MARTIN (FR)

(72) Inventors: Julien VITIELLO, GRENOBLE (FR); Jean-Luc DELCARRI, SAINT-ISMIER (FR); Fabien PIALLAT, MONTBONNOT-SAINT-MARTIN (FR)

(73) Assignee: KOBUS SAS, MONTBONNOT-SAINT-MARTIN (FR)

(21) Appl. No.: 15/775,984

(22) PCT Filed: Nov. 15, 2016
(86) PCT No.: PCT/FR2016/052956

§ 371 Date: May 14, 2018

(30) Foreign Application Priority Data
Nov. 16, 2015 (FR) 1560933

(51) Int. Cl. C23C 16/56; C23C 16/455; C23C 16/12

(52) U.S. Cl. CPC C23C 16/56; C23C 16/12; C23C 16/45527

(57) ABSTRACT

The present invention relates to a method for producing a layer (2) of aluminum oxide and/or aluminum nitride (Al₂O₃, or AIN) on a substrate (1), said method comprising a sequence of consecutive steps a) and b) according to which: a) a basic layer of aluminum (21, 22) having a thickness between 5 and 25 nm is deposited on the substrate (1) in a deposition chamber (10), b) the substrate (1) is moved into a treatment chamber (20) separate from the deposition chamber (10), in which the basic layer of aluminum (21, 22) is oxidized or nitrided to produce a basic layer of aluminum oxide or aluminum nitride (21′ 22′). Said sequence of consecutive steps is repeated in a loop until said layer of aluminum oxide and/or aluminum nitride (2) is obtained by stacking the consecutive layers of aluminum oxide and aluminum nitride (21′ 22′).

### FIELD OF THE INVENTION

This invention relates to a method for producing aluminium oxide and/or aluminium nitride, as well as a device for implementing such a method.

### STATE OF THE ART

To form a layer of aluminium oxide or aluminium nitride (Al₂O₃) or (AIN), to produce semiconductor materials for example, the use of an Atomic Layer Deposition or ALD process in a deposition chamber is known. An atomic layer of aluminium is deposited on a substrate in a deposition chamber. After the deposition of the aluminium layer, the deposition chamber is purged. Oxygen or ammonia is then sent into the deposition chamber to oxidize or nitride the atomic layer of aluminium, so as to form a layer of aluminium oxide or aluminium nitride. The deposition chamber is again purged before the deposition of a new atomic layer of aluminium. The aluminium deposition, oxidation or nitriding steps and the purges are repeated until the desired thickness for the layer of aluminium oxide or aluminium nitride is obtained.

However, the atomic layer deposition process is relatively slow, since it involves depositing only one atomic layer at a time. Thus, to form a layer of aluminium oxide or aluminium nitride of 50 to 100 nm thick, the process lasts several hours. In addition, when implementing this method, a deposit may form on the walls of the deposition chamber, but this deposit is difficult to clean. Indeed, cleaning the aluminium oxide deposits by dipping in etch baths is known, but this technique is not suitable for cleaning a deposition chamber.

To compensate for the low deposition rate, the method of arranging several substrates in the deposition chamber in order to simultaneously obtain an aluminium oxide layer on several substrates is known. However, the simultaneous presence of several substrates causes a decrease in the homogeneity of the atmosphere of the deposition chamber, which penalizes the quality of the deposit, particularly with regard to the homogeneity of the thickness of the layers deposited.

It is these disadvantages that the invention more particularly intends to remedy by proposing a method of forming a layer consisting of aluminium oxide and/or aluminium nitride and a device for implementing such a method, making it possible to facilitate the cleaning of the deposition chamber during the production of aluminium oxide layers of considerable thickness, that is to say, typically between 20 and 500 nm.

### SUMMARY OF THE INVENTION

In this regard, the purpose of the invention is to propose a method for forming a layer consisting of aluminium oxide (Al₂O₃) and/or aluminium nitride (AIN) on a substrate, in which a sequence of consecutive steps a) and b) according to which:

a) an elemental layer of aluminium with a thickness of between 5 nm and 25 nm is deposited over the substrate in a deposition chamber,

b) the substrate is moved into a treatment chamber distinct from the deposition chamber, in which the elemental layer of aluminium is oxidized and/or nitrided to form an elemental layer of aluminium oxide or aluminium nitride, respectively.

is repeated in a loop until the said layer of aluminium oxide and/or nitride is obtained by stacking consecutive elemental layers of aluminium oxide or aluminium nitride, respectively.

It should be noted that, unless otherwise indicated, the term “over” should not be interpreted to imply direct contact between two elements, but covers the possible existence of at least one element inserted between the two elements in question.

According to other advantageous but non-obligatory features of the invention, such a method may incorporate one or more of the following features, taken in any technically permissible combination:
during step b), the oxidation or nitriding is carried out by diffusing oxygen or nitrogen atoms through the elemental layer of aluminium;
only one substrate at a time is laid out in the deposition chamber and in the treatment chamber;
steps a) and b) are repeated until the thickness of the layer of aluminium oxide and/or nitride is greater than or equal to 20 nm, and preferably less than 500 nm;
during step a), the elemental layer of aluminium is deposited by means of a physical vapour deposition (PVD) or chemical vapour deposition (CVD) method;
the method further includes a step c), in which:
the substrate coated with the oxide layer and/or aluminium nitride is moved into an intermediate chamber separate from the deposition chamber and the treatment chamber and sealed with respect to said deposition and treatment chambers, then
the deposition chamber and/or the treatment chamber are cleaned.

The invention may be carried out in a device which comprises a sealed deposition chamber connected to an aluminium source, a sealed treatment chamber connected to an oxygen or nitrogen source and an intermediate chamber to which the deposition chamber and the treatment chamber are connected separately and tightly.

### BRIEF DESCRIPTION OF DRAWINGS

The invention will be better understood upon reading the description which follows, given with reference to the appended drawings in which:

FIGS. 1A to 1E illustrate various stages of a method for producing aluminium oxide and/or aluminium nitride according to the invention; and

FIG. 2 is a diagram of a device for implementing the method for producing aluminium oxide and/or aluminium nitride.

For purposes of readability of the figures, the various elements illustrated are not necessarily represented to scale.

### DETAILED DESCRIPTION OF THE INVENTION

The layer of aluminium oxide and/or aluminium nitride is formed by stacking elemental layers of aluminium oxide and/or aluminium nitride on a substrate.

The function of the substrate is to serve as a support for the layer of aluminium oxide and/or aluminium nitride to be formed.

Each elemental layer is formed in two consecutive steps each made in a specific vacuum chamber of a deposition device.

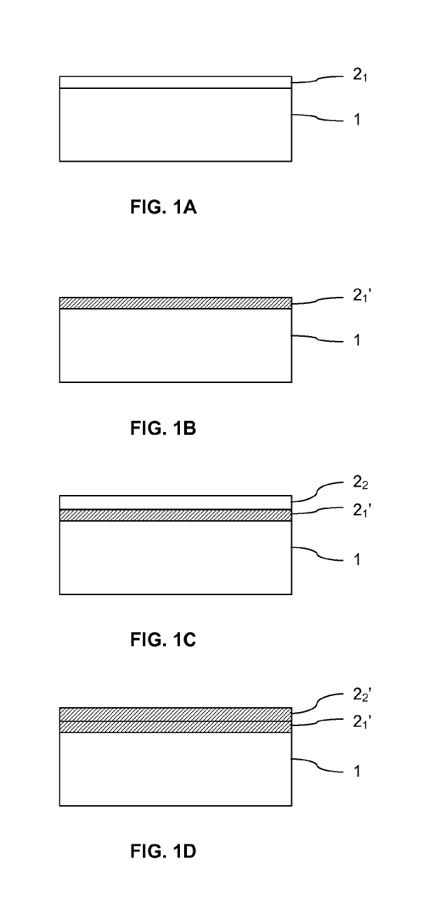

In a first step, illustrated in FIG. 1A, a first elemental layer 2₁ of aluminium is deposited on a substrate 1 in a first chamber, known as deposition chamber. For this purpose, in the case of chemical vapour deposition (CVD), molecules containing aluminium atoms are introduced into the vacuum chamber and react with the surface of the substrate to form an aluminium layer on the surface of the substrate.

The thickness of this elemental layer is chosen to be fine enough to allow the subsequent diffusion of oxygen atoms (in the case of oxidation) or nitrogen (in the case of nitriding) throughout the thickness of the said layer. In this regard, it is considered that said elemental aluminium layer must have a thickness of between 5 and 25 nm, preferably between 5 and 20 nm, or even between 5 and 15 nm.

If the elemental layer of aluminium had a greater thickness, oxidation would lead to the formation of a surface layer of aluminium oxide (extending from the surface of the elemental layer exposed to the oxidizing atmosphere to the substrate) which, as from a thickness of about ten nanometres, would form a barrier to the oxidation of the underlying portion of the elemental layer of aluminium. Under these conditions, the underlying portion could not be oxidized and would obtain a composite layer formed from a surface portion of aluminium oxide and a buried portion of aluminium.

The deposition of the elemental layer of aluminium can be carried out by means of a physical vapour deposition (PVD) method or chemical vapour deposition (CVD) method which are much faster than the atomic layer deposition process.

The deposition of such an elemental layer of aluminium lasts about twenty seconds.

The substrate carrying the first elemental layer of aluminium is then moved into a second chamber, known as treatment chamber. The treatment chamber is separate from the deposition chamber and impervious to it.

In the treatment chamber, species containing oxygen or nitrogen are injected so as to generate an oxidation or nitriding of the elemental layer of aluminium 2₁. During this treatment, oxygen or nitride atoms diffuse through the first elemental layer of aluminium 2₁ over the entire thickness of said layer. Thus, depending on the species injected, a first elemental layer 2-T of aluminium oxide or aluminium nitride is obtained (see FIG. 1B).

The oxidation or nitriding of the elemental layer of aluminium takes about ten seconds.

Then, the substrate 1 coated with the first elemental layer 2₁′ of aluminium oxide or aluminium nitride is brought back into the deposition chamber.

Particularly advantageously, all the movements of the substrates are carried out within the device under vacuum or in a controlled atmosphere so as to avoid any contamination of the deposited layers.

In the deposition chamber, a second elemental layer 2₂ of aluminium is deposited on the first elemental layer 2₁′ of aluminium oxide or aluminium nitride (see FIG. 1C). The characteristics of this deposition step of the second elemental layer of aluminium are similar to those of the deposition step of the first elemental layer of aluminium.

The substrate coated with layers 2₁′ and 2₂ is then moved into the treatment chamber, where oxidation or nitriding of the second elemental layer 2₂ of aluminium is carried out so as to form a second elemental layer 2₂′ aluminium oxide or aluminium nitride (see FIG. 1D).

The characteristics of this treatment step of the second elemental layer of aluminium are similar to those of the treatment step of the first elemental layer of aluminium.

Then, the substrate 1 coated with the elemental layer 2₁′ and 2₂′ of aluminium oxide or aluminium nitride is brought back into the deposition chamber.

Depending on the intended application, it is possible to carry out the same treatment (oxidation or nitriding) in all the treatment steps of the method, or alternatively to apply an oxidation treatment and a nitriding treatment in order to obtain a stack of elementary layers of aluminium oxide and aluminium nitride. In the latter case, a device including two treatment chambers is advantageously used, one being connected to an oxygen source and the other to a nitrogen source, and the substrate coated with the elemental layer of aluminium to be treated is placed in one of these two chambers according to the treatment to be carried out.

The sequence of deposition of an elemental layer of aluminium and of oxidation or nitriding of said elemental layer of aluminium is thus repeated several times until the desired thickness for the layer of aluminium oxide and/or aluminium nitride is obtained.

Thus, at the end of n implementations of this sequence (n being an integer greater than or equal to 2), as illustrated in FIG. 1E, a stack of elemental layers 2₁′, 2₂′, . . . 2ₙ′ oxide and/or aluminium nitride on the substrate 1 is obtained, this stack forming the desired layer 2 of aluminium oxide and/or aluminium nitride.

Particularly advantageously, the layer 2 has a thickness greater than or equal to 20 nm, and preferably less than 500 nm.

One advantage of this method is that by carrying out the deposition of aluminium in a chamber dedicated for this purpose, which does not receive oxygen or nitrogen, the formation of a difficult-to-clean aluminium oxide or aluminium nitride deposit on the inner walls of the deposition chamber is avoided.

Another advantage of this method is that the formation of each elemental layer of aluminium oxide or aluminium nitride is very rapid (up to about thirty seconds), which makes it possible to obtain thick layers of aluminium oxide and/or aluminium nitride in a few minutes, which is much faster than existing methods.

Consequently, even by putting a single substrate in the deposition chamber or in the treatment chamber at each stage of the process—which advantageously makes it possible to minimize the inhomogeneities of the layer of aluminium oxide and/or aluminium nitride—the method remains economically competitive.

We will now describe an example of a device for forming a layer of aluminium oxide and/or aluminium nitride according to the method described above.

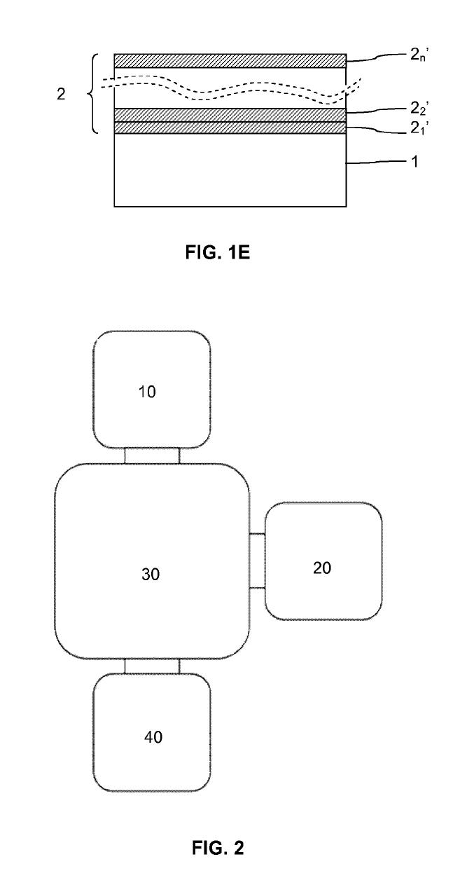

Referring to FIG. 2, said device comprises a sealed deposition chamber 10 which can be placed under vacuum, connected to an aluminium source (not shown) as well as a sealed treatment chamber connected to an oxygen or a nitrogen source (not shown). The device possibly comprises two treatment chambers, one connected to an oxygen source and the other to a nitrogen source.

The device further comprises an inlet/outlet airlock 40 through which the substrates on which a layer of aluminium oxide and/or aluminium nitride must be formed are introduced and through which the substrates on which said layer of aluminium oxide and/or aluminium nitride has been formed are removed.

Said inlet/outlet airlock 40 opens into a sealed intermediate chamber 30, which can connect separately with the deposition chamber 10 and with the treatment chamber(s) 20. A substrate handling and transport system (not shown) is arranged inside the device to allow movement of the substrate from one chamber to another.

The atmosphere in the chamber 30 is controlled, so as to avoid contamination of a substrate flowing between the different chambers.

Thus, during the formation of the layer of aluminium oxide and/or aluminium nitride, the substrate moves between the intermediate chamber 30, the deposition chamber 10 and the treatment chamber 20, the said chambers being fluidly isolated from each other during the implementation of the steps of the method. Thus, any mutual contamination of the rooms that may generate difficult-to-clean deposits on the inner walls of the rooms is avoided.

Once a substrate or several substrates have been coated with the layer of aluminium oxide and/or aluminium nitride, the substrate is removed from the device through the intermediate chamber 30 and then through the inlet/outlet airlock chamber 40 and the cleaning of at least one chamber of the device can be carried out.

Insofar as no deposit resulting from a reaction between aluminium and oxygen or nitrogen has formed on the walls of the chambers, this cleaning is easy to implement using the techniques available to those skilled in the art, for example by chlorine chemistry, type Cl₂+BCI_{3.}

Thus, the cleaning of the device is relatively fast and does not affect the productivity of the method.

1. A method for forming a layer consisting of aluminium oxide (Al₂O₃) and/or aluminium nitride (AlN) on a substrate in which a sequence of consecutive steps a) and b) according to which:
a) an elemental layer of aluminium with a thickness of between 5 nm and 25 nm is deposited on the substrate in a deposition chamber,
b) the substrate is moved into a treatment chamber separate from the deposition chamber, in which the elemental layer of aluminium is oxidized and/or nitrided to form an elemental layer of aluminium oxide or aluminium nitride, respectively,
is repeated in a loop until the said layer of aluminium oxide and/or nitride is obtained by stacking consecutive elemental layers of aluminium oxide or aluminium nitride, respectively.

2. Method according to claim 1, characterized in that during step b), the oxidation or nitriding is carried out by diffusing oxygen or nitrogen atoms respectively through the elemental layer of aluminium.

3. The method according to claim 1, characterized in that only one substrate at a time is laid out in the deposition chamber and in the treatment chamber.

4. The method according to claim 1, characterized in that steps a) and b) are repeated until the thickness of the layer of aluminium oxide and/or aluminium nitride is greater than or equal to 20 nm, and preferably less than 500 nm.

5. The method according to claim 1, characterized in that during step a), the elemental layer of aluminium is deposited by means of a physical vapour deposition (PVD) or Chemical Vapour Deposition (CVD) method.

6. The method according to claim 1, characterized in that it further comprises a step c), wherein:
the substrate coated with the layer of aluminium oxide and/or aluminium nitride is moved into an intermediate chamber separate from the deposition chamber and the treatment chamber and sealed with respect to said deposition and treatment chambers, then
the deposition chamber and/or the treatment chamber are cleaned.

7. The method according to claim 2, characterized in that only one substrate at a time is laid out in the deposition chamber and in the treatment chamber.

8. The method according to claim 2, characterized in that steps a) and b) are repeated until the thickness of the layer of aluminium oxide and/or aluminium nitride is greater than or equal to 20 nm, and preferably less than 500 nm.

9. The method according to claim 3, characterized in that steps a) and b) are repeated until the thickness of the layer of aluminium oxide and/or aluminium nitride is greater than or equal to 20 nm, and preferably less than 500 nm.

10. The method according to claim 2, characterized in that during step a), the elemental layer of aluminium is deposited by means of a physical vapour deposition (PVD) or Chemical Vapour Deposition (CVD) method.

11. The method according to claim 3, characterized in that during step a), the elemental layer of aluminium is deposited by means of a physical vapour deposition (PVD) or Chemical Vapour Deposition (CVD) method.

12. The method according to claim 4, characterized in that during step a), the elemental layer of aluminium is deposited by means of a physical vapour deposition (PVD) or Chemical Vapour Deposition (CVD) method.

13. The method according to claim 2, characterized in that it further comprises a step c), wherein:
the substrate coated with the layer of aluminium oxide and/or aluminium nitride is moved into an intermediate chamber separate from the deposition chamber and the treatment chamber and sealed with respect to said deposition and treatment chambers, then
the deposition chamber and/or the treatment chamber are cleaned.

14. The method according to claim 3, characterized in that it further comprises a step c), wherein:
the substrate coated with the layer of aluminium oxide and/or aluminium nitride is moved into an intermediate chamber separate from the deposition chamber and the treatment chamber and sealed with respect to said deposition and treatment chambers, then
the deposition chamber and/or the treatment chamber are cleaned.

15. The method according to claim 4, characterized in that it further comprises a step c), wherein:
the substrate coated with the layer of aluminium oxide and/or aluminium nitride is moved into an intermediate chamber separate from the deposition chamber and the treatment chamber and sealed with respect to said deposition and treatment chambers, then
the deposition chamber and/or the treatment chamber are cleaned.

16. The method according to claim 5, characterized in that it further comprises a step c), wherein:
the substrate coated with the layer of aluminium oxide and/or aluminium nitride is moved into an intermediate chamber separate from the deposition chamber and the treatment chamber and sealed with respect to said deposition and treatment chambers, then
the deposition chamber and/or the treatment chamber are cleaned.
